(19) United States
(12) Patent Application Publication
(10) Pub. No.: US 2025/0167128 A1
(43) Pub. Date: May 22, 2025

(54) SEMICONDUCTOR PACKAGE INCLUDING A SOLDER BALL

(71) Applicant: SAMSUNG ELECTRONICS CO., LTD., Suwon-Si (KR)

(72) Inventors: Junghoon KANG, Suwon-si (KR); Kiju LEE, Suwon-si (KR)

(21) Appl. No.: 18/808,327

(22) Filed: Aug. 19, 2024

(30) Foreign Application Priority Data
Nov. 21, 2023 (KR) 10-2023-0162730

(51) Int. Cl. H01L 23/544; H01L 23/31; H01L 23/498

(52) U.S. Cl. CPC H01L 23/544; H01L 23/3114; H01L 23/49816; H01L 2223/54426

(57) ABSTRACT

A semiconductor package includes a package body, a semiconductor chip disposed in the package body, a first redistribution structure disposed on a lower surface of the package body and on a lower surface of the semiconductor chip, wherein the first redistribution structure includes a first redistribution element, a first redistribution pad disposed on a lower surface of the first redistribution structure and electrically connected to the first redistribution element, a ball land layer disposed on a lower surface of the first redistribution pad, a first pad insulating layer disposed on the lower surface of the first redistribution structure, wherein the first pad insulating layer insulates the first redistribution pad and the ball land layer, an alignment mark structure spaced apart from the first redistribution pad and the ball land layer and disposed inside or on a lower surface of the first pad insulating layer, and a first solder ball disposed on a lower surface of each of the first redistribution pad and the ball land layer.

### CROSS-REFERENCE TO RELATED APPLICATION

This application is based on and claims priority under 35 U.S.C. § 119 to Korean Patent Application No. 10-2023-0162730, filed on Nov. 21, 2023, in the Korean Intellectual Property Office, the disclosure of which is incorporated by reference herein in its entirety.

### 1. TECHNICAL FIELD

The present inventive concept relates to a semiconductor package, and more particularly, to a semiconductor package including a solder ball.

### 2. DISCUSSION OF THE RELATED ART

As the electronics industry advances rapidly to meet user demands for smaller, lighter electronic devices, the size of semiconductor packages, the core components of such devices, are getting smaller. Consequently, the process of forming or arranging solder balls or capacitors within these semiconductor packages is becoming challenging.

### SUMMARY

The present inventive concept provides a semiconductor package capable of easily forming (or arrange) solder balls or capacitors.

According to an aspect of the inventive concept, there is provided a semiconductor package including a package body, a semiconductor chip disposed in the package body, a first redistribution structure disposed on a lower surface of the package body and on a lower surface of the semiconductor chip, wherein the first redistribution structure includes a first redistribution element, a first redistribution pad disposed on a lower surface of the first redistribution structure and electrically connected to the first redistribution element, a ball land layer disposed on a lower surface of the first redistribution pad, a first pad insulating layer disposed on the lower surface of the first redistribution structure, wherein the first pad insulating layer insulates the first redistribution pad and the ball land layer, an alignment mark structure spaced apart from the first redistribution pad and the ball land layer and disposed inside or on a lower surface of the first pad insulating layer, and a first solder ball disposed on a lower surface of each of the first redistribution pad and the ball land layer.

According to another aspect of the inventive concept, there is provided a semiconductor package including a package body having a fan-in area and a fan-out area at least partially surrounding the fan-in area, wherein a body wiring structure is formed in the fan-out area of the package body, a semiconductor chip disposed in the fan-in area, a first redistribution structure disposed on a lower surface of the package body and a lower surface of the semiconductor chip, and comprising a first redistribution element in each of the fan-in area and the fan-out area, a first redistribution pad disposed on a lower surface of the first redistribution structure and electrically connected to the first redistribution element, a ball land layer disposed on a lower surface of the first redistribution pad, a first pad insulating layer disposed on the lower surface of the first redistribution structure and insulating the first redistribution pad and the ball land layer, an alignment mark structure disposed in the fan-out area and spaced apart from the first redistribution pad, and disposed inside or on a lower surface of the first pad insulating layer, and a first solder ball disposed on the lower surface of the first redistribution pad and a lower surface of the ball land layer.

According to another aspect of the inventive concept, there is provided a semiconductor package including a lower package and an upper package stacked on the lower package. The lower package includes a package body having a fan-in area and a fan-out area at least partially surrounding the fan-in area, wherein a body wiring structure is formed in the fan-out area of the package body, a lower semiconductor chip disposed in the fan-in area, a first redistribution structure disposed on a lower surface of the package body and a lower surface of a lower semiconductor chip, and comprising a first redistribution element in each of the fan-in area and the fan-out area, a first redistribution pad disposed on a lower surface of the first redistribution structure and electrically connected to the first redistribution element, a ball land layer disposed on a lower surface of the first redistribution pad, a first pad insulating layer disposed on the lower surface of the first redistribution structure and insulating the first redistribution pad and the ball land layer, an alignment mark structure disposed in the fan-out area and spaced apart from the first redistribution pad, and disposed inside or on a lower surface of the first pad insulating layer, a first solder ball disposed on a lower surface of each of the first redistribution pad and the ball land layer, a second redistribution structure disposed on an upper surface of the package body and an upper surface of the lower semiconductor chip, and comprising a second redistribution element in each of the fan-in area and the fan-out area, and a second redistribution pad electrically connected to the second redistribution element. The upper package includes a second solder ball disposed on the second redistribution pad and an upper semiconductor chip mounted on the second redistribution structure and electrically connected through the second solder ball.

### BRIEF DESCRIPTION OF THE DRAWINGS

Embodiments will be more clearly understood from the following detailed description taken in conjunction with the accompanying drawings in which:

FIG. 1 is a cross-sectional view of main portions of a semiconductor package according to an embodiment;

FIG. 2 is an enlarged view of a portion “EN1” of FIG. 1;

FIG. 3 is a cross-sectional view of main portions of a semiconductor package according to an embodiment;

FIG. 4 is a cross-sectional view of main portions of a semiconductor package according to an embodiment;

FIG. 5 is a cross-sectional view of main portions of a semiconductor package according to an embodiment;

FIG. 6 is a cross-sectional view of a modified embodiment of the semiconductor package of FIGS. 1 and 2.

FIG. 7 is a cross-sectional view of a modified embodiment of the semiconductor package of FIGS. 1 and 2;

FIG. 8 is a cross-sectional view of a modified embodiment of the semiconductor package of FIGS. 1 and 2;

FIG. 9 is a cross-sectional view of a modified embodiment of the semiconductor package of FIGS. 1 and 2;

FIG. 10 is a cross-sectional view of a modified embodiment of the semiconductor package of FIGS. 1 and 2;

FIG. 11 is a cross-sectional view of a modified embodiment of the semiconductor package of FIGS. 1 and 2;

FIGS. 12, 13, 14, 15, 16 and 17 are cross-sectional views of a method of manufacturing the semiconductor package of FIGS. 1 and 2;

FIG. 18 is a perspective view for explaining a process of forming a ball land hole in a method of manufacturing a semiconductor package of the inventive concept;

FIGS. 19, 20 and 21 are cross-sectional views of main portions for explaining a manufacturing method of the semiconductor package of FIG. 4, according to an embodiment;

FIG. 22 is a cross-sectional view of main portions of a semiconductor package according to an embodiment;

FIG. 23 is a block diagram showing a configuration of a semiconductor package according to an embodiment; and

FIG. 24 is a block diagram schematically showing a configuration of a semiconductor package according to an embodiment.

### DETAILED DESCRIPTION OF THE EMBODIMENTS

Hereinafter, embodiments of the present inventive concept will be described in detail with reference to the attached drawings. The same or similar reference signs or numerals are used for identical components in the drawings, and to the extent that an element is not described in detail with respect to this figure, it may be understood that the element is at least similar to a corresponding element that has been described elsewhere within the present disclosure.

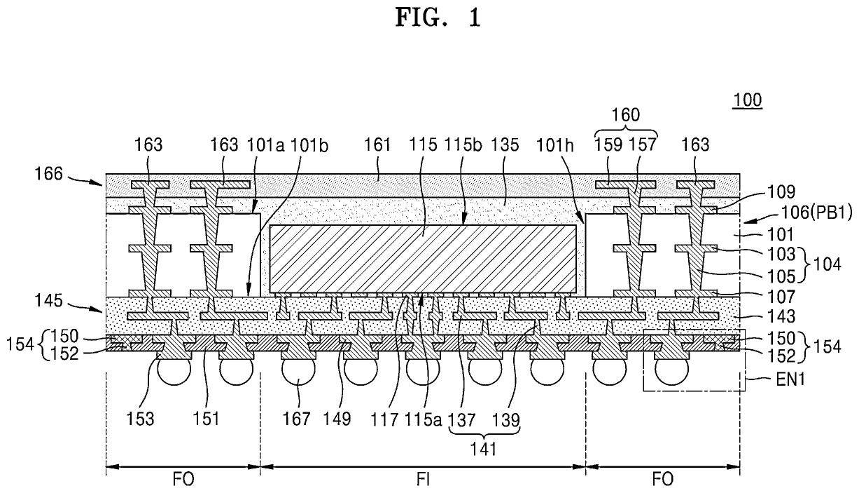

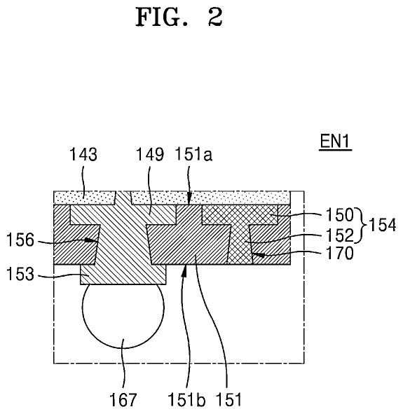

FIG. 1 is a cross-sectional view of main portions of a semiconductor package 100 according to an embodiment. FIG. 2 is an enlarged view of a portion “EN1” of FIG. 1.

For example, the semiconductor package 100 may be a fan-out semiconductor package. The semiconductor package 100 may include a wiring board 106 having a fan-in area FI corresponding to a through hole 101h disposed therein, and fan-out areas FO located on both sides of the fan-in area FI. For example, the fan-out area FO may at least partially surround the fan-in area FI in a plan view.

The wiring board 106 may be a package body PB1. The package body PB1 may be a package element. The wiring board 106 may be an insulating board. The wiring board 106 may be a printed circuit board. The wiring board 106 may be called a frame board. The semiconductor package 100 may be a Fan Out Panel Level Package (FOPLP). The wiring board 106 may include a body 101 located on each of both sides of a through hole 101h, a board wiring structure 104 formed in the body 101, and board wiring pads 107 and 109.

The through hole 101h may penetrate an upper surface 101a and a lower surface 101b of the body 101. The body 101 may include at least one material selected from phenol resin, epoxy resin, and polyimide. For example, the body 101 may include at least one material selected from Frame Retardant 4 (FR4), tetrafunctional epoxy, polyphenylene ether, epoxy/polyphenylene oxide, bismaleimide triazine (BT), THERMOUNT (a non-MDA polyimide resin system produced by DuPont Company), cyanate ester, polyimide, and liquid crystal polymer.

The board wiring structure 104 may include board wiring layers 103 formed in the body 101 and a board via 105 connecting the board wiring layers 103 to each other. For example, the board via 105 may be in direct contact with the board wiring layers 103 that are vertically spaced apart from each other. The board wiring pads 107 and 109 may each include a first board wiring pad 107 located on the lower surface 101b of the body 101 and electrically connected to the board wiring structure 104, and a second board wiring pad 109 located on the upper surface 101a of the body 101 and electrically connected to the board wiring structure 104. For example, the board wiring layers 103 and the board via 105 may be disposed between the first board wiring pads 107 and the second board wiring pad 109.

The first board wiring pad 107 may be a part of the board wiring layer 103 located on the lower surface 101b of the body 101. The second board wiring pad 109 may be a part of the board wiring layer 103 located on the upper surface 101a of the body 101.

The board wiring layer 103, the board via 105, and the board wiring pads 107 and 109 may each include a metal layer. For example, the board wiring layer 103, the first board wiring pads 107 and the second board wiring pads 109 may each include an electrolytically deposited (ED) copper foil, a rolled-annealed (RA) copper foil, a stainless steel foil, aluminum foil, an ultra-thin copper foils, sputtered copper, a copper alloy, etc. The board via 105 may include, for example, copper, nickel, stainless steel, or beryllium copper.

The semiconductor package 100 may include a semiconductor chip 115 disposed in the through hole 101h. The semiconductor chip 115 may be a fan-in chip structure. In some embodiments, the wiring board 106 corresponding to the semiconductor chip 115 may correspond to the fan-out area FO. A body part of the wiring board 106 excluding the through hole 101h may correspond to the fan-out area FO. In some embodiments, the semiconductor chip 115 may be embedded in the through hole 101h. In the embodiment, the semiconductor chip 115 may include one chip or a plurality of chips.

In some embodiments, the semiconductor chip 115 may include an individual device. The individual device may include various microelectronics devices, for example, a metal-oxide-semiconductor field effect transistor (MOSFET) such as a complementary metal-insulator-semiconductor (CMOS) transistor, an image sensor such as system large scale integration (LSI), a CMOS imaging sensor (CIS), a micro-electro-mechanical system (MEMS), an active device, a passive device, etc.

The semiconductor chip 115 may be a logic chip, a power management integrated circuit (PMIC chip), or a memory chip. In some embodiments, the logic chip may be a memory controller chip, a central processing unit (CPU) chip, a graphics processing unit (GPU) chip, or an application processor (AP) chip.

In some embodiments, the memory chip may be a dynamic random access memory (DRAM) chip, a static random access memory (SRAM) chip, a flash memory chip, an electrically erasable and programmable read-only memory (EPROM) chip, a phase-change random access memory (PRAM) chip, a magnetic random access memory (MRAM) chip, or a resistive random access memory (RRAM) chip.

The semiconductor chip 115 may include a lower surface 115a and an upper surface 115b. The lower surface 115a may be an active surface on which individual devices are formed, and the upper surface 115b may be an inactive surface on which individual devices are not formed. For example, the semiconductor chip 115 includes the lower surface 115a facing down which is the active surface on which individual devices are formed. A chip pad 117 may be disposed on the lower surface 115a of the semiconductor chip 115. The chip pad 117 may be a metal pad such as an aluminum pad or a copper pad. The chip pad 117 may be an electrically conductive pad.

The semiconductor package 100 may include a first redistribution structure 145. The first redistribution structure 145 may be disposed below a lower surface 101b of the wiring board 106 and a lower surface 115a of the semiconductor chip 115. The first redistribution structure 145 may include a first redistribution insulating layer 143 and a first redistributed redistribution element 141 horizontally extending towards the fan-out area FO. The first redistribution insulating layer 143 and the first redistributed redistribution element 141 may be redistributed within the first redistribution insulating layer 143.

The first redistribution insulating layer 143 may include insulating polymer or a silicon-containing insulating material. The insulating polymer may include, for example, photosensitive polyimide (PSPI), polybenzoxazole (PBO), phenolic polymer, and/or benzocyclobutene polymer (BCB). The silicon-containing insulating material may include silicon oxide, silicon nitride, silicon oxynitride, and/or tetraethyl orthosilicate (TEOS).

The first redistribution element 141 may include a first redistribution layer 137 and a first redistribution via 139 connected to the first redistribution layer 137. The first redistribution element 141 may be electrically connected to the chip pad 117 disposed in the fan-in area FI. The first redistribution element 141 may include the same material as the board wiring structure 104.

The first redistribution structure 145 may include a first redistribution pad 149 electrically connected to the first redistribution element 141. The first redistribution pad 149 may be a part of the first redistribution layer 137. For example, the first redistribution pad 149 and the first redistribution layer 137 may form a unified structure. The first redistribution pad 149 may include the same material as the first board wiring pads 107 and the second board wiring pads 109.

A ball land layer 153, for example, a nickel layer or a copper layer, may be formed on a lower surface of the first redistribution pad 149. The ball land layer 153 may be formed inside a ball land hole 156 formed in a first pad insulating layer 151, as shown in FIG. 2. The ball land layer 153 may be a barrier metal layer. The first redistribution pad 149 and the ball land layer 153 may be electrically insulated from each other by the first pad insulating layer 151. For example, the first pad insulating layer 151 may be disposed between and in direct contact with the first redistribution pad 149 and the ball land layer 153.

In FIG. 2, a lower surface 151b of the first pad insulating layer 151 is not the same as a lower surface of the ball land layer 153. However, in some embodiments, the lower surface 151b of the first pad insulating layer 151 may be the same as the lower surface 151b of the ball land layer 153. The first redistribution pad 149 may be electrically separated from the ball land layer 153 by the first pad insulating layer 151. A first solder ball 167 may be formed on the lower surface of each of the first redistribution pad 149 and the ball land layer 153. The first solder ball 167 may be a first external connection terminal.

In some embodiments, the first pad insulating layer 151 may include the same material as the first redistribution insulating layer 143. In some embodiments, the first pad insulating layer 151 may include an Ajinomoto Build-up Film (ABF). The ABF may include epoxy resin (including epoxy, a hardener, and an additive) and inorganic filler (e.g., silicon oxide). In some embodiments, the first pad insulating layer 151 may include photo imageable dielectric (PID).

The semiconductor package 100 may include an alignment mark structure 154. The alignment mark structure 154 may be spaced apart from the first redistribution pad 149 and the ball land layer 153 and may be disposed inside the first pad insulating layer 151. The first pad insulating layer 151 may have an upper surface 151a and a lower surface 151b as shown in FIG. 2.

As shown in FIG. 2, the alignment mark structure 154 may include a first alignment mark 150 formed in the first pad insulating layer 151 at the same level as the first redistribution pad 149, and a second alignment mark 152 embedded in an alignment mark hole 170 while exposing the first alignment mark 150 in the first insulating layer 151. The alignment mark hole 170 may be formed by etching the first pad insulating layer 151 in a direction from the lower surface 151b of the first pad insulating layer 151 to the upper surface 151a. The alignment mark hole 170 may have an intaglio shape formed inside the first pad insulating layer 151, meaning that it has shapes with defined edges and contours.

In some embodiments, the alignment mark structure 154 may include either the first alignment mark 150 or the second alignment mark 152. The alignment mark structure 154 may include a metal layer. The alignment mark structure 154 may include the same material as the board wiring structure 104.

The first alignment mark 150 may be formed simultaneously with the formation of the first redistribution pad 149. In some embodiments, the alignment mark hole 170 may be formed by applying a laser beam to the first pad insulating layer 151. In some embodiments, the alignment mark hole 170 may be formed using a photoetching process. The second alignment mark 152 may be formed simultaneously with the formation of the ball land layer 153. The second alignment mark 152 may be formed by filling a metal layer in the alignment mark hole 170 by using a plating process.

In some embodiments, the first alignment mark 150 and the second alignment mark 152 may each be a real pattern or a ground pattern that is electrically connected to the semiconductor chip 115. In some embodiments, the first alignment mark 150 and the second alignment mark 152 may each be a dummy pattern that is not electrically connected to the semiconductor chip 115.

The alignment mark structure 154 may be provided to easily perform mask alignment when forming the ball land hole 156 for forming the ball land layer 153 and the first solder ball 167. For example, when performing mask alignment for forming the ball land hole 156, the alignment mark structure 154 may be easily recognized by a camera. Accordingly, the first solder ball 167 may be easily formed on the package body PB1, that is, on the lower surface of the wiring board 106.

The semiconductor package 100 may include an encapsulation layer 135. The encapsulation layer 135 may be formed on the semiconductor chip 115 and the wiring board 106 embedded in the through hole 101h. For example, the encapsulation layer 135 may at least partially surround the semiconductor chip 115 and the wiring board 106. The encapsulation layer 135 may be formed on each of both sides of the semiconductor chip 115 in the through hole 101h. The encapsulation layer 135 may surround the semiconductor chip 115 in the through hole 101h in a plan view. The encapsulation layer 135 may include, for example, an epoxy molding compound (EMC).

The semiconductor package 100 may include a second redistribution structure 166. The second redistribution structure 166 may be disposed on the upper surface 101a of the wiring board 106 and the upper surface 115b of the semiconductor chip 115. The second redistribution structure 166 may include a second redistribution insulating layer 161 and a second redistribution element 160. The second redistribution insulating layer 161 may include the same material as the first redistribution insulating layer 143 or the first pad insulating layer 151.

The second redistribution structure 166 may include the second redistribution element 160 formed on the encapsulation layer 135 and insulated by the second redistribution insulating layer 161. The second redistribution element 160 may include a second redistribution layer 159 and a second redistribution via 157. The second redistribution element 160 may be electrically connected to the board wiring structure 104. The second redistribution element 160 may include the same material as the board wiring structure 104.

The second redistribution structure 166 may include a second redistribution pad 163 electrically connected to the second redistribution element 160. The second redistribution pad 163 may be a part of the second redistribution layer 159. The second redistribution pad 163 may be electrically connected to the second redistribution layer 159.

The second redistribution pad 163 may be electrically separated from other elements by the second pad insulating layer 161. The second redistribution pad 163 may include the same material as the board wiring pads 107 and 109. A second solder ball may be connected onto the second redistribution pad 163.

As described above, the semiconductor package 100 of the present inventive concept may include the alignment mark structure 154 spaced apart from the first redistribution pad 149 and the ball land layer 153 and formed inside the first pad insulating layer 151. The semiconductor package 100 of the present inventive concept may easily perform mask alignment for forming the first solder ball 167 by using the alignment mark structure 154. Accordingly, the semiconductor package 100 of the present inventive concept may easily form the first solder ball 167 on the package body PB1, that is, on the lower surface of the wiring board 106.

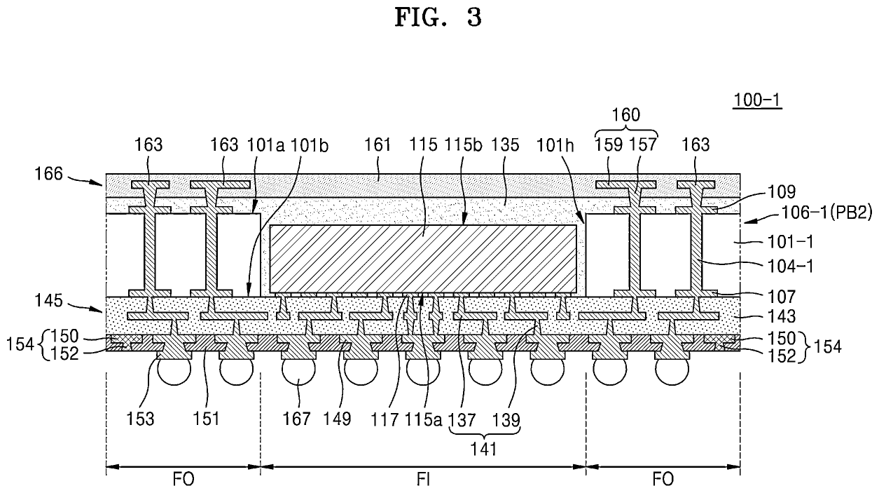

FIG. 3 is a cross-sectional view of main portions of a semiconductor package 100-1 according to an embodiment.

The semiconductor package 100-1 may be substantially the same as the semiconductor package 100 of FIGS. 1 and 2 except for a wiring board 106-1. To the extent that an element has not been described in detail, it may be assumed that the element is at least similar to corresponding elements that have been described in previous figures.

The semiconductor package 100-1 may include the wiring board 106-1. The wiring board 106-1 may be a package body PB2. The package body PB2 may be a package element. The wiring board 106-1 may be a semiconductor substrate.

The semiconductor package 100-1 may be a fan-out wafer level package (FOWLP). The wiring board 106-1 may include a body 101-1, a board wiring structure 104-1 located in the body 101-1, and board wiring pads 107 and 109.

The body 101-1 may include a semiconductor material, for example, a semiconductor element such as silicon (Si) or germanium (Ge), or a compound semiconductor such as silicon carbide (SiC), gallium arsenide (GaAs), indium arsenide (InAs), and indium phosphide (InP). The board wiring structure 104-1 may be a board wiring layer formed in the body 101-1. The board wiring layer 103 (refer to FIG. 1) may include a metal layer, for example, copper. As described above, the semiconductor package 100-1 may use a semiconductor substrate as the wiring board 106-1.

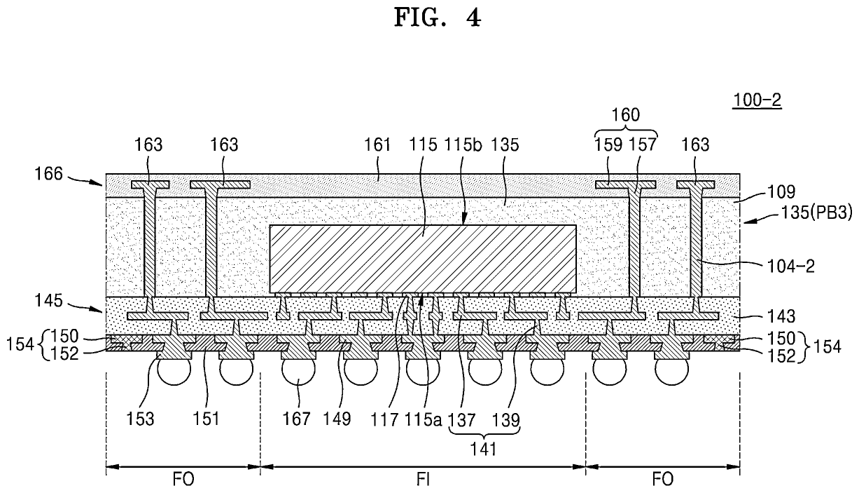

FIG. 4 is a cross-sectional view of main portions of a semiconductor package 100-2 according to an embodiment.

The semiconductor package 100-2 may be substantially the same as the semiconductor package 100 of FIGS. 1 and 2 except for a package body PB3 and a body wiring structure 104-2. To the extent that an element has not been described in detail, it may be assumed that the element is at least similar to corresponding elements that have been described in previous figures.

The semiconductor package 100-2 may include the encapsulation layer 135. The encapsulation layer 135 may be the package body PB3. The package body PB3 may be a package element. The semiconductor package 100-4 may be a FOWLP.

The body wiring structure 104-2 may be formed in the encapsulation layer 135. The body wiring structure 104-2 may include a metal post, for example, a copper post. The body wiring structure 104-2 may be a body wiring layer. As described above, the semiconductor package 100-2 may use the encapsulation layer 135 as the package body PB3.

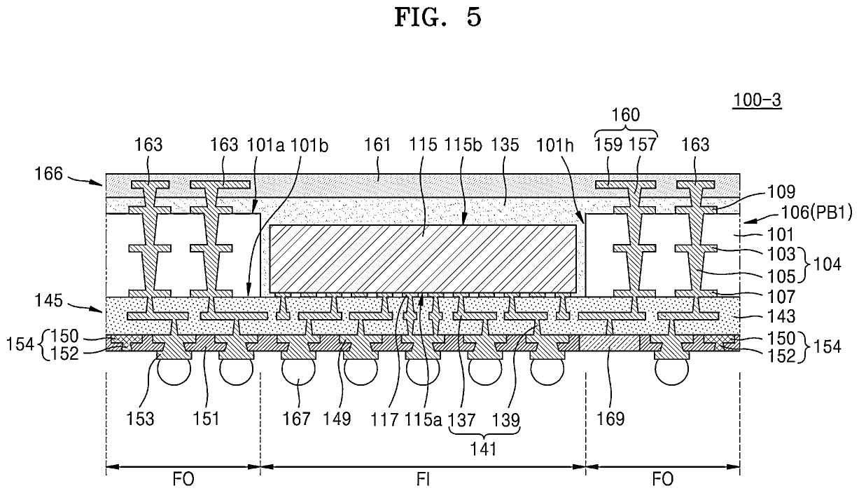

FIG. 5 is a cross-sectional view of main portions of a semiconductor package 100-3 according to an embodiment.

The semiconductor package 100-3 may be substantially the same as the semiconductor package 100 of FIGS. 1 and 2 except that a capacitor 169 is further formed on a lower portion of the wiring board 106. To the extent that an element has not been described in detail, it may be assumed that the element is at least similar to corresponding elements that have been described in previous figures.

The semiconductor package 100-3 may include the capacitor 169. The capacitor 169 may be formed in a lower portion of the first redistribution structure 145. The capacitor 169 may be electrically connected to the first redistribution element 141 of the first redistribution structure 145. The capacitor 169 may be formed in the first pad insulating layer 151.

The alignment mark structure 154 may be provided and facilitate mask alignment when forming the capacitor 169. For example, when performing mask alignment for forming the capacitor hole 168, the alignment mark structure 154 may be easily recognized by a camera. Accordingly, the capacitor 169 may be easily formed on the package body PB1, that is, on the lower surface of the wiring board 106.

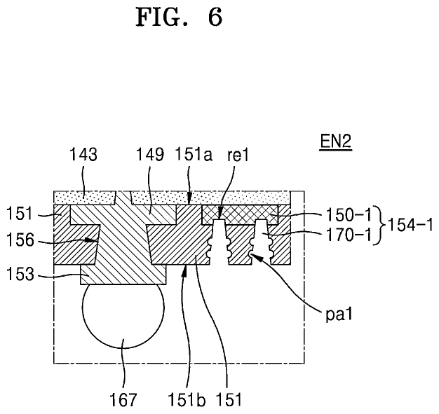

FIG. 6 is a cross-sectional view of a modified embodiment EN2 of the semiconductor package 100 of FIGS. 1 and 2.

The modified embodiment EN2 may correspond to the portion EN1 of the semiconductor package 100 of FIGS. 1 and 2. To the extent that an element has not been described in detail, it may be assumed that the element is at least similar to corresponding elements that have been described in previous figures.

The modified embodiment EN2 may include the first redistribution pad 149, the first pad insulating layer 151, the ball land layer 153, and the first solder ball 167. The ball land layer 153, for example, a nickel layer or a copper layer, may be formed on a lower surface of the first redistribution pad 149. The ball land layer 153 may be formed inside the ball land hole 156 formed in the first pad insulating layer 151.

The first redistribution pad 149 may be electrically separated from other elements by the first pad insulating layer 151. The first pad insulating layer 151 may have the upper surface 151a and the lower surface 151b. The first solder ball 167 may be formed on a lower surface of each of the first redistribution pad 149 and the ball land layer 153. In some embodiments, the first pad insulating layer 151 may include an ABF.

The modified embodiment EN2 may include an alignment mark structure 154-1. The alignment mark structure 154-1 may be spaced apart from the first redistribution pad 149 and the ball land layer 153 and formed inside the first pad insulating layer 151.

The alignment mark structure 154-1 may include a first alignment mark 150-1 formed in the first pad insulating layer 151 at the same level as the first redistribution pad 149, and an alignment mark hole 170-1 exposing the first alignment mark 150-1 in the first insulating layer 151.

In some embodiments, the alignment mark hole 170-1 may be formed by applying a laser beam to the first pad insulating layer 151. The alignment mark hole 170-1 may be formed by etching the first pad insulating layer 151 with a laser beam in a direction from the lower surface 151b of the first pad insulating layer 151 to the upper surface 151a. Accordingly, the alignment mark hole 170-1 may have an intaglio shape formed inside the first pad insulating layer 151, meaning that it has shapes with defined edges and contours.

A curved surface pa1 may be formed on a side wall inside the alignment mark hole 170-1 by laser beam etching. In addition, the first alignment mark 150-1 may have a surface recess portion rel. That is, the first alignment mark 150-1 may have a lower surface recessed inward.

In some embodiments, the first alignment mark 150-1 may include a metal layer. The first alignment mark 150-1 may include the same material as the board wiring structure 104. The first alignment mark 150-1 may be formed simultaneously with the formation of the first redistribution pad 149.

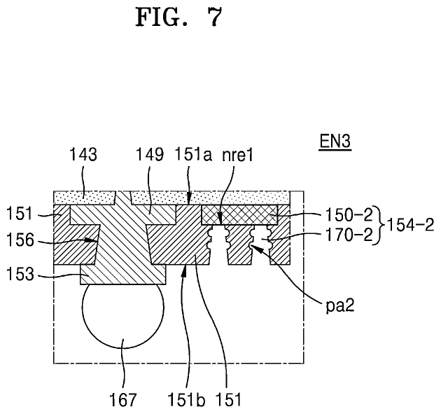

FIG. 7 is a cross-sectional view of a modified embodiment EN3 of the semiconductor package 100 of FIGS. 1 and 2.

The modified embodiment EN3 may correspond to the portion EN1 of the semiconductor package 100 of FIGS. 1 and 2. To the extent that an element has not been described in detail, it may be assumed that the element is at least similar to corresponding elements that have been described in previous figures.

The modified embodiment EN3 may include the first redistribution pad 149, the first pad insulating layer 151, the ball land layer 153, and the first solder ball 167. The ball land layer 153, for example, a nickel layer or a copper layer, may be formed on a lower surface of the first redistribution pad 149. The ball land layer 153 may be formed inside the ball land hole 156 formed in the first pad insulating layer 151.

The first redistribution pad 149 may be electrically separated from other elements by the first pad insulating layer 151. The first pad insulating layer 151 may have the upper surface 151a and the lower surface 151b. The first solder ball 167 may be formed on a lower surface of each of the first redistribution pad 149 and the ball land layer 153. In some embodiments, the first pad insulating layer 151 may include an ABF.

The modified embodiment EN3 may include an alignment mark structure 154-2. The alignment mark structure 154-2 may be spaced apart from the first redistribution pad 149 and the ball land layer 153 and formed inside the first pad insulating layer 151. The alignment mark structure 154-2 may include a first alignment mark 150-2 formed in the first pad insulating layer 151 at the same level as the first redistribution pad 149, and an alignment mark hole 170-2 while exposing the first alignment mark 150-2 in the first insulating layer 151.

In some embodiments, the alignment mark hole 170-2 may be formed by applying a laser beam to the first pad insulating layer 151. The alignment mark hole 170-2 may be formed by etching the first pad insulating layer 151 with a laser beam in a direction from the lower surface 151b of the first pad insulating layer 151 to the upper surface 151a. Accordingly, the alignment mark hole 170-2 may have an intaglio shape formed inside the first pad insulating layer 151, meaning that it has shapes with defined edges and contours.

A curved surface pa2 may be formed on a side wall inside the alignment mark hole 170-2 by laser beam etching. In addition, a surface nrel of the first alignment mark 150-2 might not be recessed. In some embodiments, the first alignment mark 150-2 may include a metal layer. The first alignment mark 150-2 may be formed simultaneously with the formation of the first redistribution pad 149.

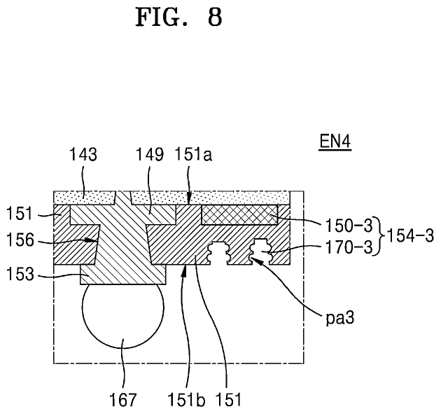

FIG. 8 is a cross-sectional view of a modified embodiment EN4 of the semiconductor package 100 of FIGS. 1 and 2.

The modified embodiment EN4 may correspond to the portion EN1 of the semiconductor package 100 of FIGS. 1 and 2. To the extent that an element has not been described in detail, it may be assumed that the element is at least similar to corresponding elements that have been described in previous figures.

The modified embodiment EN4 may include the first redistribution pad 149, the first pad insulating layer 151, the ball land layer 153, and the first solder ball 167. The ball land layer 153, for example, a nickel layer or a copper layer, may be formed on a lower surface of the first redistribution pad 149. The ball land layer 153 may be formed inside the ball land hole 156 formed in the first pad insulating layer 151.

The first redistribution pad 149 may be electrically separated from other elements by the first pad insulating layer 151. The first pad insulating layer 151 may have the upper surface 151a and the lower surface 151b. The first solder ball 167 may be formed on a lower surface of each of the first redistribution pad 149 and the ball land layer 153. In some embodiments, the first pad insulating layer 151 may include an ABF.

The modified embodiment EN4 may include an alignment mark structure 154-3. The alignment mark structure 154-3 may be spaced apart from the first redistribution pad 149 and the ball land layer 153 and formed inside the first pad insulating layer 151. The alignment mark structure 154-3 may include a first alignment mark 150-3 formed in the first pad insulating layer 151 at the same level as the first redistribution pad 149, and an alignment mark hole 170-3 that does not expose the first alignment mark 150-3 in the first insulating layer 151.

In some embodiments, the alignment mark hole 170-3 may be formed by applying a laser beam to the first pad insulating layer 151. The alignment mark hole 170-3 may be formed by etching the first pad insulating layer 151 with a laser beam in a direction from the lower surface 151b of the first pad insulating layer 151 to the upper surface 151a. Accordingly, the alignment mark hole 170-3 may have an intaglio shape formed inside the first pad insulating layer 151, meaning that it has shapes with defined edges and contours.

A curved surface pa3 may be formed on a side wall inside the alignment mark hole 170-3 by laser beam etching. In some embodiments, the first alignment mark 150-3 may include a metal layer. The first alignment mark 150-3 may be formed simultaneously with the formation of the first redistribution pad 149.

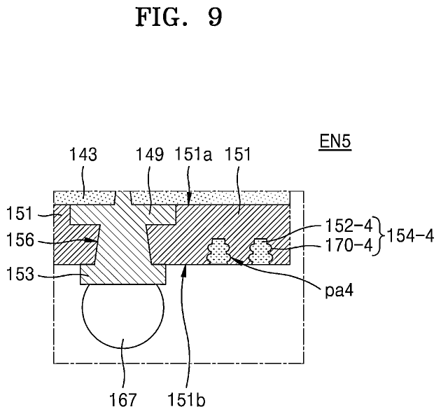

FIG. 9 is a cross-sectional view of a modified embodiment EN5 of the semiconductor package 100 of FIGS. 1 and 2.

The modified embodiment EN5 may correspond to the portion EN1 of the semiconductor package 100 of FIGS. 1 and 2. To the extent that an element has not been described in detail, it may be assumed that the element is at least similar to corresponding elements that have been described in previous figures.

The modified embodiment EN5 may include the first redistribution pad 149, the first pad insulating layer 151, the ball land layer 153, and the first solder ball 167. The ball land layer 153, for example, a nickel layer or a copper layer, may be formed on a lower surface of the first redistribution pad 149. The ball land layer 153 may be formed inside the ball land hole 156 formed in the first pad insulating layer 151.

The first pad insulating layer 151 may have the upper surface 151a and the lower surface 151b. The first solder ball 167 may be formed on a lower surface of each of the first redistribution pad 149 and the ball land layer 153. In some embodiments, the first pad insulating layer 151 may include an ABF.

The modified embodiment EN5 may include an alignment mark structure 154-4. The alignment mark structure 154-4 may be spaced apart from the first redistribution pad 149 and the ball land layer 153 and formed inside the first pad insulating layer 151.

The alignment mark structure 154-4 may include an alignment mark hole 170-4 formed in the first pad insulating layer 151 at the same level as the ball land layer 153, and an alignment mark 152-4 embedded in the alignment mark hole 170-4.

In some embodiments, the alignment mark hole 170-4 may be formed by applying a laser beam to the first pad insulating layer 151. The alignment mark hole 170-4 may be formed by etching the first pad insulating layer 151 with a laser beam in a direction from the lower surface 151b of the first pad insulating layer 151 to the upper surface 151a. Accordingly, the alignment mark hole 170-4 may be in a shape formed inside the first pad insulating layer 151, that is, an intaglio shape.

A curved surface pa4 may be formed on a side wall inside the alignment mark hole 170-4 by laser beam etching. In some embodiments, the alignment mark 152-4 may include a metal layer.

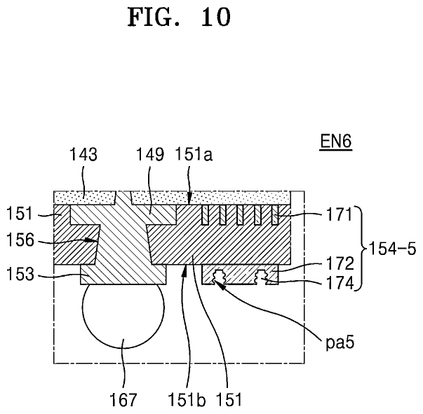

FIG. 10 is a cross-sectional view of a modified embodiment EN6 of the semiconductor package 100 of FIGS. 1 and 2.

The modified embodiment EN6 may correspond to the portion EN1 of the semiconductor package 100 of FIGS. 1 and 2. To the extent that an element has not been described in detail, it may be assumed that the element is at least similar to corresponding elements that have been described in previous figures.

The modified embodiment EN6 may include the first redistribution pad 149, the first pad insulating layer 151, the ball land layer 153, and the first solder ball 167. The ball land layer 153, for example, a nickel layer or a copper layer, may be formed on a lower surface of the first redistribution pad 149. The ball land layer 153 may be formed inside the ball land hole 156 formed in the first pad insulating layer 151.

The first pad insulating layer 151 may have the upper surface 151a and the lower surface 151b. The first solder ball 167 may be formed on a lower surface of each of the first redistribution pad 149 and the ball land layer 153. In some embodiments, the first pad insulating layer 151 may include an ABF. In some embodiments, the first pad insulating layer 151 may include PID.

The modified embodiment EN6 may include an alignment mark structure 154-5. The alignment mark structure 154-5 may be spaced apart from the first redistribution pad 149 and the ball land layer 153 and formed inside the first pad insulating layer 151. The alignment mark structure 154-5 may include a first alignment mark 171 formed in the first pad insulating layer 151 at the same level as the first redistribution pad 149 and including strip patterns spaced apart from each other, a second alignment mark 172 formed on a lower surface of the first pad insulating layer 151, and an alignment mark hole 174 formed in the second alignment mark 172.

In some embodiments, the alignment mark structure 154-5 may include either the first alignment mark 171 or the second alignment mark 172. In some embodiments, the alignment mark hole 174 may be formed by applying a laser beam to the second alignment mark 172. The alignment mark hole 174 may be formed by etching the second alignment mark 172 with a laser beam in a direction from a lower surface of the second alignment mark 172 to an upper surface. Accordingly, the alignment mark hole 174 may be formed in an intaglio shape.

A curved surface pa5 may be formed on a side wall inside the alignment mark hole 174 by laser beam etching. In some embodiments, the first alignment mark 171 and the second alignment mark 172 may each include a metal layer. The first alignment mark 171 may be formed at the same time as the formation of the first redistribution pad 149.

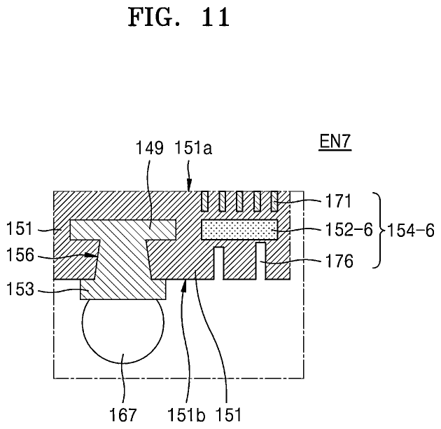

FIG. 11 is a cross-sectional view of a modified embodiment EN7 of the semiconductor package 100 of FIGS. 1 and 2.

For example, the modified embodiment EN7 may correspond to the portion EN1 of the semiconductor package 100 of FIGS. 1 and 2. To the extent that an element has not been described in detail, it may be assumed that the element is at least similar to corresponding elements that have been described in previous figures.

The modified embodiment EN7 may include the first redistribution pad 149, the first pad insulating layer 151, the ball land layer 153, and the first solder ball 167. The ball land layer 153, for example, a nickel layer or a copper layer, may be formed on a lower surface of the first redistribution pad 149. The ball land layer 153 may be formed inside the ball land hole 156 formed in the first pad insulating layer 151.

The first pad insulating layer 151 may have the upper surface 151a and the lower surface 151b. The first solder ball 167 may be formed on a lower surface of each of the first redistribution pad 149 and the ball land layer 153. In some embodiments, the first pad insulating layer 151 may include PID.

The modified embodiment EN7 may include an alignment mark structure 154-6. The alignment mark structure 154-6 may be spaced apart from the first redistribution pad 149 and the ball land layer 153 and formed inside the first pad insulating layer 151. The alignment mark structure 154-6 may include the first alignment mark 171 formed in the first pad insulating layer 151 and including strip patterns, a second alignment mark 152-6 formed in the pad insulating layer 151 at the same level as the first redistribution pad 149, and an alignment mark hole 176 exposing the second alignment mark 152-6 in the first pad insulating layer 151.

In some embodiments, the alignment mark structure 154-6 may include either the first alignment mark 171 or the second alignment mark 152-6. In some embodiments, the alignment mark hole 176 may be formed by photoetching the first pad insulating layer 151. Accordingly, the alignment mark hole 176 may have an intaglio shape formed inside the first pad insulating layer 151, meaning that it has shapes with defined edges and contours.

In some embodiments, the first alignment mark 171 and the second alignment mark 152-6 may each include a metal layer. The second alignment mark 152-6 may be formed simultaneously with the formation of the first redistribution pad 149.

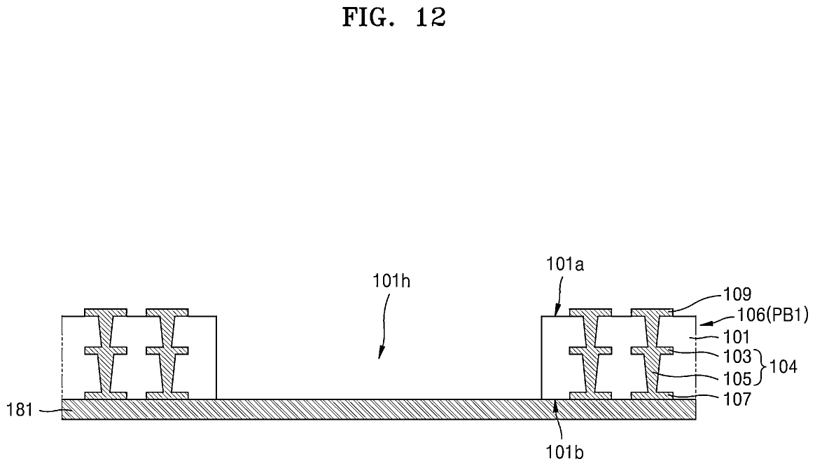

FIGS. 12 to 17 are cross-sectional views of a method of manufacturing the semiconductor package 100 of FIGS. 1 and 2.

In FIGS. 12 to 17, the same reference numerals as in FIGS. 1 and 2 indicate the same members. To the extent that an element has not been described in detail, it may be assumed that the element is at least similar to corresponding elements that have been described in previous figures.

Referring to FIG. 12, the wiring board 106 having the through hole 101h is prepared. The wiring board 106 constitutes the package body PB1. The wiring board 106 may be an insulating board. The wiring board 106 may include the body 101 located on each of both sides of the through hole 101h, the board wiring structure 104 formed in the body 101, and the board wiring pads 107 and 109.

The board wiring structure 104 may include the board wiring layers 103 formed in the body 101 and the board via 105 connecting the board wiring layers 103 to each other. For example, the board via 105 may be in direct contact with the board wiring layers 103 that are vertically spaced apart from each other. The board wiring pads 107 and 109 may each include the first board wiring pad 107 located on the lower surface 101b of the body 101, and the second board wiring pad 109 located on the upper surface 101a of the body 101. The first board wiring pad 107 may be a part of the board wiring layer 103 located on the lower surface 101b of the body 101. The second board wiring pad 109 may be a part of the board wiring layer 103 located on the upper surface 101a of the body 101.

Subsequently, the wiring board 106 in which the through hole 101h is formed is attached onto a tape board 181. The wiring board 106 is attached onto the tape board 181 such that the second board wiring pad 109 located on the lowermost surface is attached to the tape board 181. In this case, the through hole 101h is located in the center of the tape board 181, and the body 101 may be located on each of both sides of the tape board 181. For example, the through hole 101h may be disposed between the bodies 101 disposed on each end of the tape board 181.

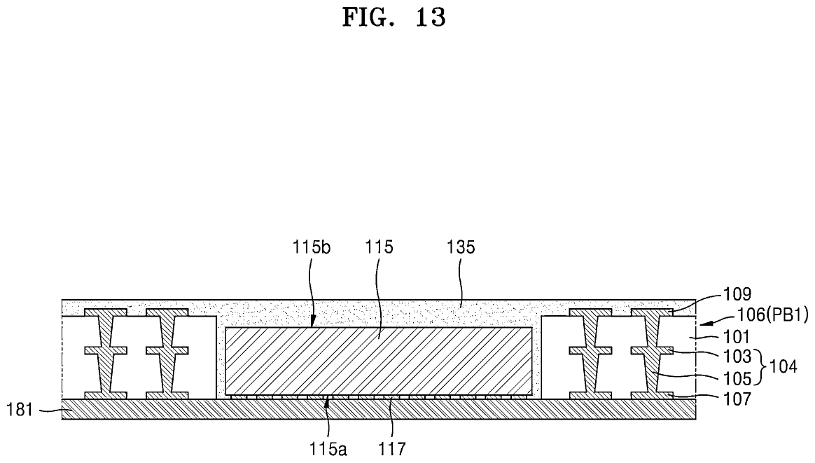

Referring to FIG. 13, the semiconductor chip 115 is attached to the tape board 181 with the chip pad 117 facing down in the through hole 101h of the wiring board 106. The semiconductor chip 115 is attached to the tape board 181 with an active surface, that is, the lower surface 115a on which the chip pad 117 is formed, facing down.

In this case, the semiconductor chip 115 may be located in the through hole 101h. When attaching the semiconductor chip 115 to the tape board 181, the semiconductor chip 115 may be spaced apart from a side surface of the wiring board 106.

Subsequently, the encapsulation layer 135 is formed on the tape board 181 to seal the semiconductor chip 115 and the wiring board 106. The encapsulation layer 135 is formed thick enough to sufficiently seal the semiconductor chip 115 and the wiring board 106. The encapsulation layer 135 is formed to be thicker than the upper surface 101a of the body 101 and the surface of the semiconductor chip 115.

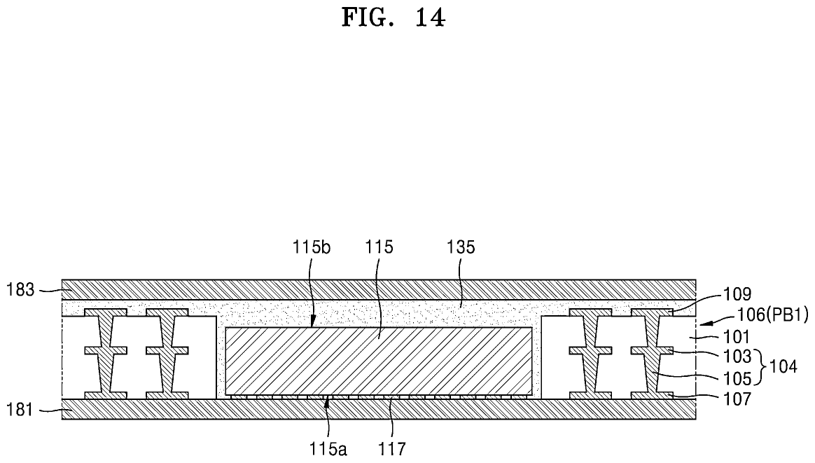

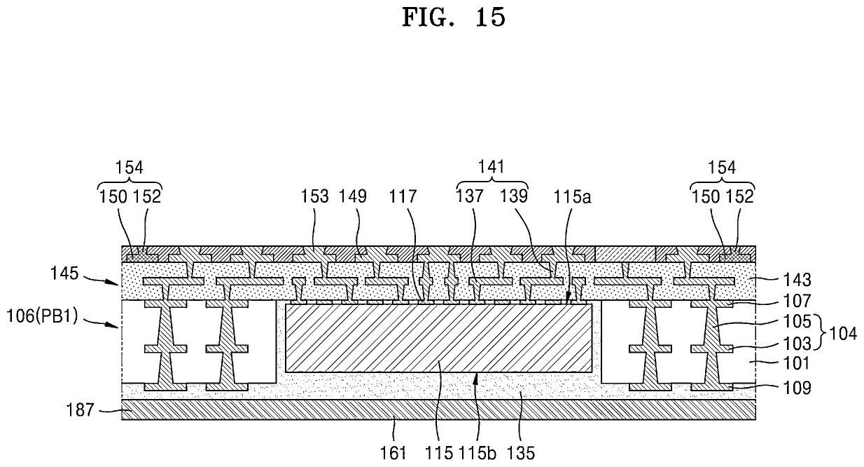

Referring to FIGS. 14 and 15, a first carrier board 183 is attached onto the encapsulation layer 135 as shown in FIG. 14. The first carrier board 183 may be an insulating board or a semiconductor substrate. Then, as shown in FIG. 15, the tape board 181 in FIG. 13 is removed.

Subsequently, the first redistribution structure 145 is formed on the lower surface 115a of the semiconductor chip 115 and the lower surface 101b of the wiring board 106. The first redistribution structure 145 may be disposed on the lower surface 101b of the wiring board 106 and the lower surface 115a of the semiconductor chip 115.

The first redistribution structure 145 may include the first redistribution insulating layer 143, the first redistribution element 141, and the first redistribution pad 149. The first redistribution element 141 may include the first redistribution layer 137 and the first redistribution via 139 connected to the first redistribution layer 137.

The first redistribution element 141 may be electrically connected to the chip pad 117. The first redistribution structure 145 may extend to the fan-out area FO in FIG. 1 and be electrically connected to the first board wiring pad 107.

The first redistribution pad 149 and the first pad insulating layer 151 are formed on the first redistribution structure 145. In some embodiments, the first pad insulating layer 151 may include an ABF. The first redistribution pad 149 may be electrically connected to the first redistribution structure 145. The first redistribution pad 149 may be a part of the first redistribution layer 137 located on an upper surface of the first redistribution insulating layer 143.

In some embodiments, when forming the first redistribution pad 149, the first alignment mark 150 constituting the alignment mark structure 154 is formed. Next, the alignment mark hole 170 in FIG. 2 exposing the first alignment mark 150 in the first pad insulating layer 151 is formed on the first alignment mark 150 through a laser beam process, and the second alignment mark 152 embedded in the alignment mark hole 170 in FIG. 2 is formed. Accordingly, the alignment mark structure 154 including the first alignment mark 150 and the second alignment mark 152 is formed.

Subsequently, the ball land hole 156 in FIG. 2 is formed in the first pad insulating layer 151 on the first redistribution pad 149 by using the alignment mark structure 154, and the ball land layer 153 in FIG. 2 is formed in the ball land hole 156 in FIG. 2.

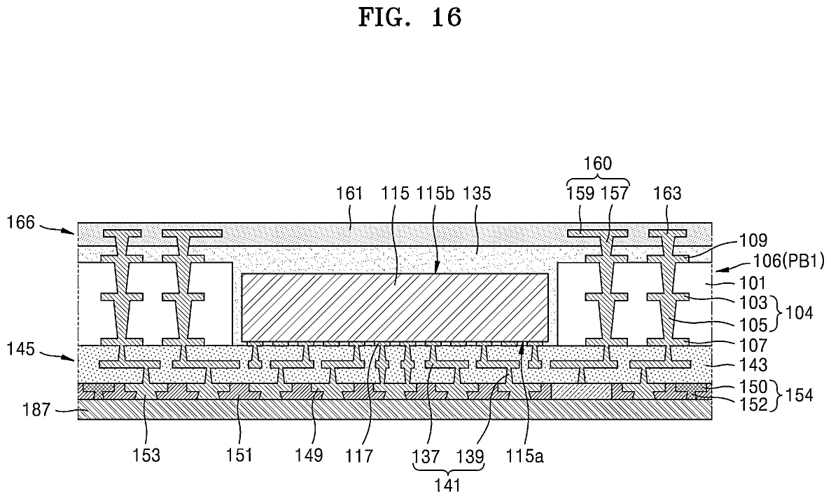

Referring to FIG. 16, the first carrier board 183 in FIG. 15 formed on the encapsulation layer 135 is removed. A second carrier board 185 is attached onto the ball land layer 153 and the first pad insulating layer 151. The second carrier board 185 may be an insulating board or a semiconductor substrate.

The second redistribution structure 166 is formed on the upper surface 101a of the wiring board 106 and the upper surface of the semiconductor chip 115. The second redistribution structure 166 may include the second redistribution element 160 formed on the encapsulation layer 135 and insulated by the second redistribution insulating layer 161. The second redistribution element 160 may include the second redistribution layer 159 and the second redistribution via 157.

The second redistribution layer 159 may be redistributed by extending to the fan-out area FO in FIG. 1 in a plan view. The second redistribution structure 166 may include the second redistribution pad 163 electrically connected to the second redistribution element 160. The second redistribution pad 163 may be a part of the second redistribution layer 159. The second redistribution pad 163 may be electrically separated from other elements by the second pad insulating layer 161.

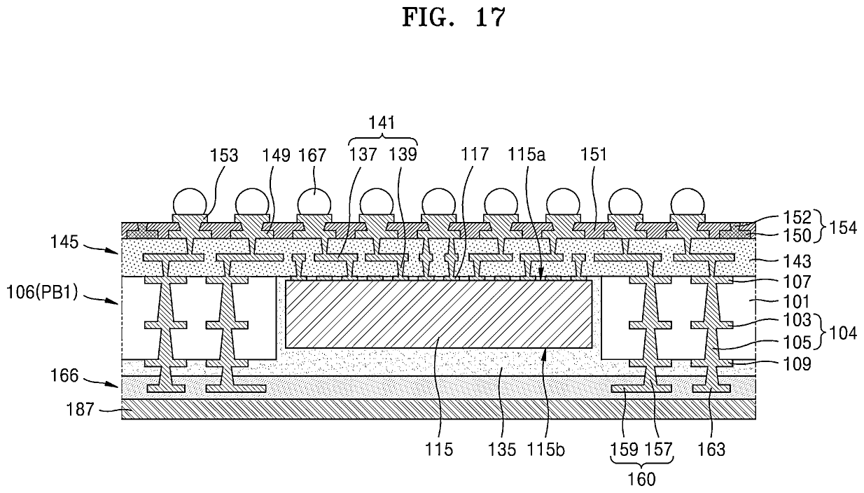

Referring to FIG. 17, the second carrier board 185 in FIG. 16 is removed. After attaching a third carrier board 187 onto the second redistribution structure 166, the first solder ball 167 is formed on the ball land layer 153. Therefore, the semiconductor package 100 shown in FIGS. 1 and 2 may be manufactured after removing the third carrier board 187.

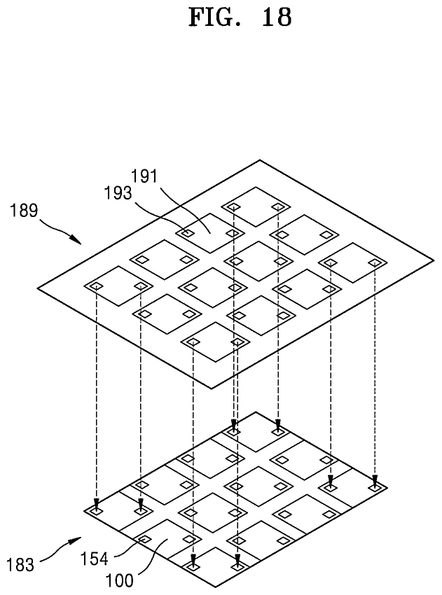

FIG. 18 is a perspective view for explaining a process of forming a ball land hole in the method of manufacturing the semiconductor package of the present inventive concept.

In FIG. 18, it may be assumed that the description is at least similar to corresponding description that have been given with reference to FIG. 15. A plurality of semiconductor packages 100 may be disposed on the first carrier board 183 in FIG. 15 as shown below in FIG. 18. Each of the semiconductor packages 100 may be referred to as an individual semiconductor package. The alignment mark structures 154 may be respectively disposed on the semiconductor packages 100. The alignment mark structures 154 may be individually disposed on the individual semiconductor package 100 as described above.

A mask 189 for forming a ball land hole may be disposed on the semiconductor packages 100 having the alignment mark structures 154. The mask 189 may have a plurality of mask areas 191 respectively arranged in accordance with the semiconductor packages 100. A plurality of mask alignment patterns 193 may be respectively disposed in the plurality of mask areas 191 in accordance with the alignment mark structures 154.

When forming the ball land hole 156 in the first pad insulating layer 151, the mask alignment patterns 193 may be aligned with the alignment mark structures 154. Accordingly, the ball land hole 156 may be easily formed in the first pad insulating layer 151, and the ball land layer 153 may be easily formed in the ball land hole 156.

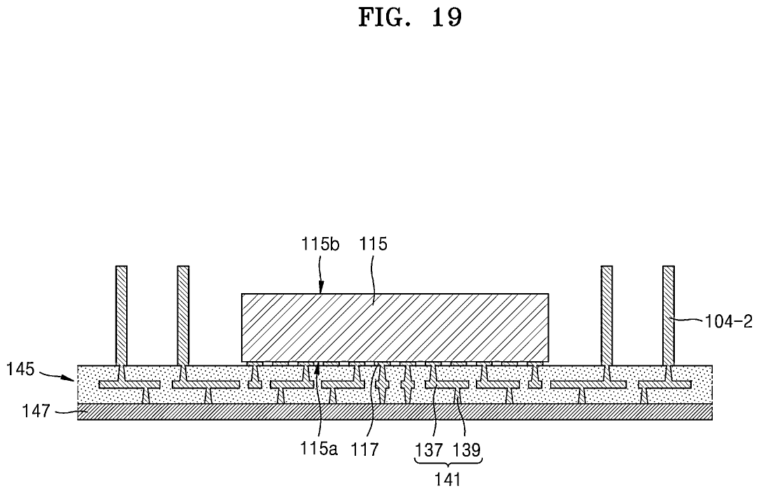

FIGS. 19 to 21 are cross-sectional views of main portions for explaining a method of manufacturing the semiconductor package 100-2 of FIG. 4 according to an embodiment.

In FIGS. 19 to 21, the same reference numerals as in FIG. 4 indicate the same members. In FIGS. 19 to 21, it may be assumed that the description is at least similar to corresponding description that have been given with reference to FIG. 4.

Referring to FIG. 18, the first redistribution structure 145 is formed on the carrier board 147. The carrier board 147 may be an insulating board or a semiconductor substrate. As described above, the first redistribution structure 145 may include the first redistribution insulating layer 143, the first redistribution element 141, and the first redistribution pad 149. The first redistribution element 141 may include the first redistribution layer 137 and the first redistribution via 139 connected to the first redistribution layer 137.

The first redistribution pad 149 may be electrically connected to the first redistribution structure 145. The first redistribution pad 149 may be a part of the first redistribution layer 137 located on an upper surface of the first redistribution insulating layer 143.

Subsequently, the body wiring structure 104-2 is formed on the first redistribution structure 145. The body wiring structure 104-2 may be formed in the fan-out area FO in FIG. 4 as previously shown. The body wiring structure 104-2 may include a metal post, for example, a copper post.

Next, the semiconductor chip 115 is mounted on the first redistribution structure 145 with the chip pad 117 facing down. The semiconductor chip 115 is mounted on the fan-in area FI in FIG. 4 with an active surface, that is, the lower surface 115a on which the chip pad 117 is formed, facing down. A thickness of the body wiring structure 104-2 may be greater than a height (or thickness) of the semiconductor chip 115.

In this case, the semiconductor chip 115 may be located in the fan-in area FI. The chip pad 117 may be electrically connected to the first redistribution element 141, for example, the first redistribution via 139.

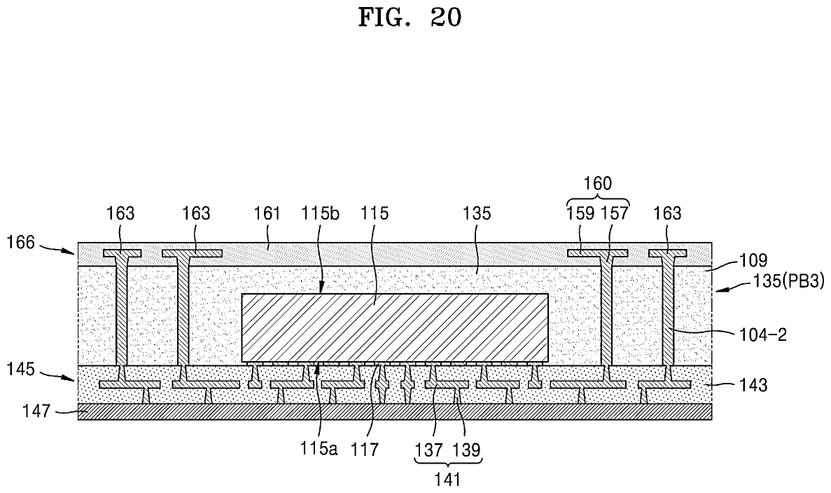

Referring to FIG. 20, the semiconductor chip 115 is sealed on the first redistribution structure 145 by forming the encapsulation layer 135 with a sufficient thickness. The encapsulation layer 135 may constitute the package body PB3. In some embodiments, the encapsulation layer 135 may have the same plane as the body wiring structure 104-2 by using a planarization process.

Subsequently, the second redistribution structure 166 is formed on the encapsulation layer 135, the semiconductor chip 115, and the body wiring structure 104-2. The second redistribution structure 166 may include the second redistribution element 160 formed in the encapsulation layer 135 and insulated by the second redistribution insulating layer 161.

The second redistribution element 160 may include the second redistribution layer 159 and the second redistribution via 157. The second redistribution structure 166 may be electrically connected to the second redistribution element 160. The second redistribution pad 163 may be a part of the second redistribution layer 159. The second redistribution pad 163 may be electrically separated from other elements by the second pad insulating layer 161.

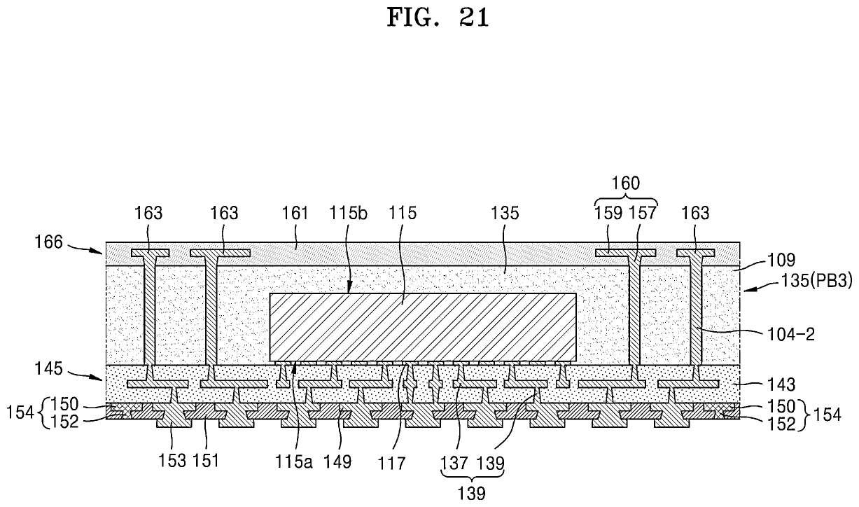

Referring to FIG. 21, the carrier board 147 in FIG. 20 is removed. Then, as shown in FIG. 4, the first redistribution pad 149 and the first pad insulating layer 151 are formed on the first redistribution structure 145. In some embodiments, the first pad insulating layer 151 may include an ABF.

In some embodiments, when forming the first redistribution pad 149, the first alignment mark 150 constituting the alignment mark structure 154 is formed. Next, the alignment mark hole 170 in FIG. 2 exposing the first alignment mark 150 in the first pad insulating layer 151 is formed on the first alignment mark 150 through a laser beam process, and the second alignment mark 152 embedded in the alignment mark hole 170 is formed. Accordingly, the alignment mark structure 154 including the first alignment mark 150 and the second alignment mark 152 is formed.

Subsequently, the ball land hole 156 in FIG. 2 is formed in the first pad insulating layer 151 on the first redistribution pad 149 by using the alignment mark structure 154, and the ball land layer 153 is formed in the ball land hole 156. An operation of forming the ball land hole 156 has been described previously, and thus, a description thereof may be assumed that the description is at least similar to corresponding description that have been given. Next, the first solder ball 167 is formed on the ball land layer 153. Therefore, the semiconductor package 100-2 shown in FIG. 4 may be manufactured.

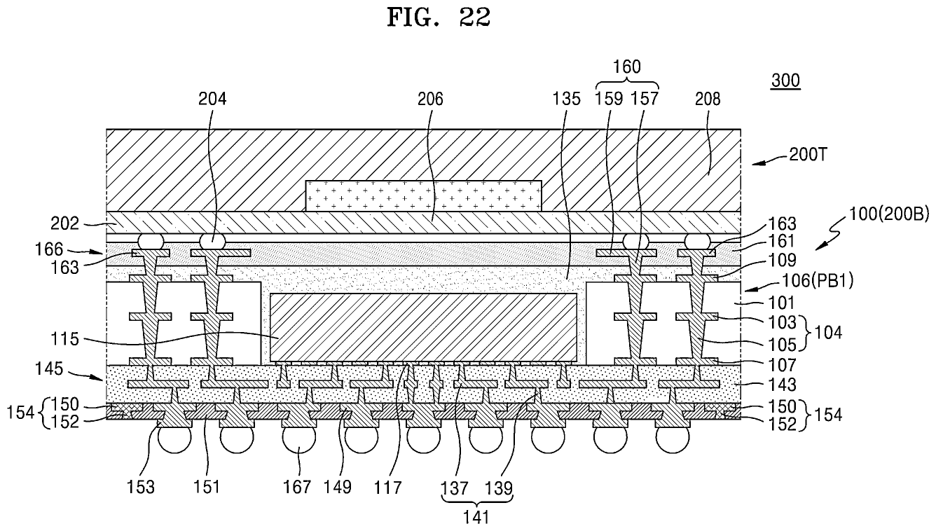

FIG. 22 is a cross-sectional view of main portions of a semiconductor package 300 according to an embodiment.

Specifically, the semiconductor package 300 may be the same as the semiconductor package 100 of FIGS. 1 and 2 except that an upper package 200T is further stacked on the semiconductor package 100 of FIGS. 1 and 2. In FIG. 22, it may be assumed that the description is at least similar to corresponding description that have been given in FIGS. 1 and 2. Here, the semiconductor package 100 of FIGS. 1 and 2 is referred to as a lower package 200B.

The semiconductor package 300 may be a stack package including the lower package 200B and the upper package 200T. A second solder ball 204 may be connected to the second redistribution pad 163 of the lower package 200B. The second solder ball 204 may be a second external connection terminal. An upper package 200T may be attached onto the second solder ball 204.

The upper package 200T may include the upper semiconductor chip 206 attached onto the upper wiring board 202. The upper wiring board 202 and the upper semiconductor chip 206 may be electrically connected to each other through a bonding wire or a bump. In FIG. 22, the upper semiconductor chip 206 may be connected to the upper wiring board 202 by using a bump. The upper semiconductor chip 206 may be a memory chip. An example of the memory chip may be as described above.

The upper package 200T may include an upper encapsulation layer 208 surrounding at least a part of the upper semiconductor chip 206. The upper encapsulation layer 208 may include, for example, an EMC. The upper encapsulation layer 208 is shown as covering an inactive surface of the upper semiconductor chip 206 (upper surface of the upper semiconductor chip 206), but is not necessarily limited thereto.

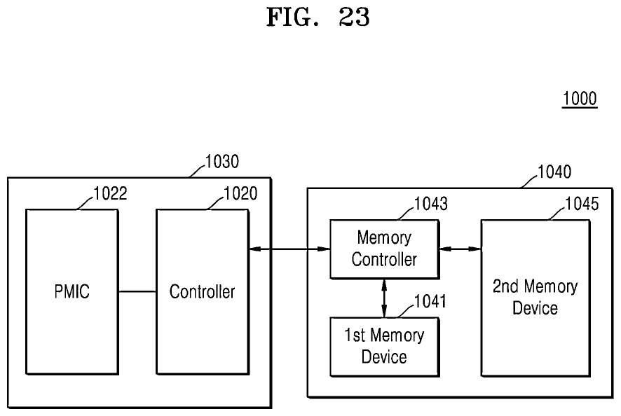

FIG. 23 is a block diagram showing a configuration of a semiconductor package 1000 according to an embodiment.

For example, the semiconductor package 1000 may correspond to the semiconductor package 100, 100-1, 100-2, or 100-3 of the present inventive concept. The semiconductor package 1000 may include a controller chip 1020, a first memory device (or a first memory chip) 1041, a second memory device (or a second memory chip) 1045, and a memory controller 1043. The semiconductor package 1000 may further include a PMIC 1022 that supplies current of an operating voltage to each of the controller chip 1020, the first memory chip 1041, the second memory chip 1045, and the memory controller 1043. Operating voltages applied to the components may be designed to be the same as or different from each other.

A lower package 1030 including the controller chip 1020 and the PMIC 1022 may be the lower package 100B of the present inventive concept described above. An upper package 1040 including the first memory device 1041, the second memory device 1045, and the memory controller 1043 may be the upper package 200T of the present inventive concept described above.

The semiconductor package 1000 may be implemented to be included in a personal computer (PC) or a mobile device. The mobile device may be implemented as a laptop computer, a mobile phone, a smartphone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile internet device (MID), a wearable computer, an Internet of things (IoT) device, an Internet of everything (IoE) device, or a drone.

The controller chip 1020 may control an operation of each of the first memory device 1041, the second memory device 1045, and the memory controller 1043. For example, the controller chip 1020 may be implemented as an integrated circuit (IC), a system on chip (SoC), an AP, a mobile AP, a chipset, or a set of chips. The controller chip 1020 may include a CPU, a GPU, and/or a modem. In some embodiments, the controller chip 1020 may perform functions of the modem and the AP.

The memory controller 1043 may control the second memory device 1045 by the control of the controller chip 1020. The first memory device 1041 may be implemented as a volatile memory device. The volatile memory device may be implemented as random access memory (RAM), dynamic RAM (DRAM), or static RAM (SRAM), but is not necessarily limited thereto. The second memory device 1045 may be implemented as a storage memory device. The storage memory device may be implemented as a non-volatile memory device.

The storage memory device may be implemented as a flash-based memory device, but is not necessarily limited thereto. The second memory device 1045 may be implemented as a NAND-type flash memory device. The NAND-type flash memory devices may include a two-dimensional (2D) memory cell array or a three-dimensional (3D) memory cell array. The 2D memory cell array or the 3D memory cell array may include a plurality of memory cells, and each of the plurality of memory cells may store 1-bit information or 2-bit or more information.

When the second memory device 1045 is implemented as the flash-based memory device, the memory controller 1043 may use (or support) a multimedia card (MMC) interface, an embedded MMC (eMMC) interface, or a universal flash storage (UFS)) interface, but is not necessarily limited to this.

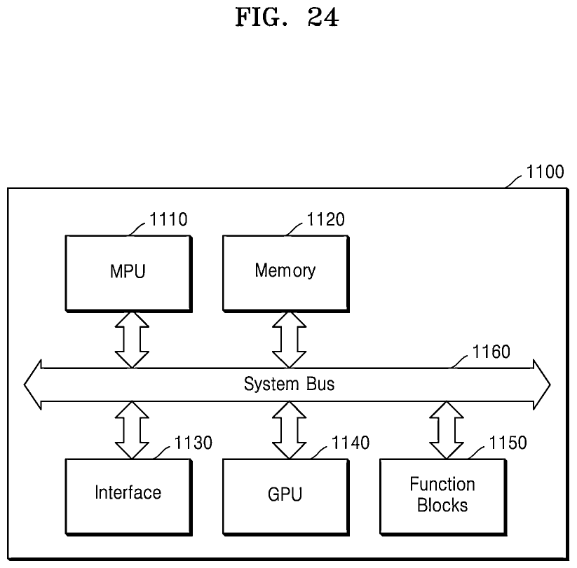

FIG. 24 is a block diagram schematically showing a configuration of a semiconductor package 1100 according to an embodiment.

For example, the semiconductor package 1100 may include a micro processing unit (MPU) 1110, a memory 1120, an interface 1130, a GPU 1140, function blocks (or functional blocks) 1150, and a bus 1160 connecting the same. The semiconductor package 1100 may include both the MPU 1110 and the GPU 1140, or may include only the MPU 1110 or the GPU 1140.

The MPU 1110 may include a core and an L2 cache. For example, the MPU 1110 may include a multi-core. Cores of the multi-core may have the same or different performance. In addition, the cores of the multi-core may be activated at the same time or at different times. The memory 1120 may store results processed by the functional blocks 1150 by the control of the MPU 1110. For example, content stored in the L2 cache of the MPU 1110 may be flushed and then stored in the memory 1120. The interface 1130 may interface with external devices. For example, the interface 1130 may interface with a camera, an LCD, and a speaker.

The GPU 1140 may perform graphics functions. For example, the GPU 1140 may perform video codec or process 3D graphics. The function blocks 1150 may perform various functions. For example, when the semiconductor package 1100 is an AP used in a mobile device, some of the functional blocks 1150 may each perform a communication function.

The semiconductor package 1100 may be the semiconductor package 100, 100-1, 100-2, 100-3, or 300 of the present inventive concept illustrated above. The MPU 1110 and/or the GPU 1140 may be the lower package 200B illustrated above. The memory 1120 may be the upper package 200T illustrated above. The interface 1130 and the function blocks 1150 may correspond to parts of the lower package 200B illustrated above.

While the present inventive concept has been particularly shown and described with reference to embodiments thereof, it will be understood that various changes in form and details may be made therein without departing from the spirit and scope of the present disclosure.

What is claimed is:

1. A semiconductor package, comprising:
a package body;
a semiconductor chip disposed in the package body;
a first redistribution structure disposed on a lower surface of the package body and on a lower surface of the semiconductor chip, wherein the first redistribution structure includes a first redistribution element;
a first redistribution pad disposed on a lower surface of the first redistribution structure and electrically connected to the first redistribution element;
a ball land layer disposed on a lower surface of the first redistribution pad;
a first pad insulating layer disposed on the lower surface of the first redistribution structure, wherein the first pad insulating layer insulates the first redistribution pad and the ball land layer;
an alignment mark structure spaced apart from the first redistribution pad and the ball land layer and disposed inside or on a lower surface of the first pad insulating layer; and
a first solder ball disposed on a lower surface of each of the first redistribution pad and the ball land layer.

2. The semiconductor package of claim 1, wherein the alignment mark structure includes:
a first alignment mark disposed in the first pad insulating layer at a same level as the first redistribution pad; and
a second alignment mark embedded in an alignment mark hole exposing the first alignment mark in the first pad insulating layer.

3. The semiconductor package of claim 1, wherein the alignment mark structure includes:
the first alignment mark disposed in the first pad insulating layer at a same level as the first redistribution pad; and
an alignment mark hole disposed in the first pad insulating layer.

4. The semiconductor package of claim 3, wherein a curved surface is further formed on a surface of the first pad insulating layer in the alignment mark hole.

5. The semiconductor package of claim 1, wherein the alignment mark structure includes:
the first alignment mark disposed in the first pad insulating layer at a same level as the first redistribution pad; and
an alignment mark hole exposing the first alignment mark disposed in the first pad insulating layer.

6. The semiconductor package of claim 5, wherein a surface recess portion is further formed on a surface of the first alignment mark in the alignment mark hole.

7. The semiconductor package of claim 1, wherein the alignment mark structure includes:
the alignment mark hole disposed in the first pad insulating layer at a same level as the ball land layer; and
an alignment mark embedded in the alignment mark hole.

8. The semiconductor package of claim 1, wherein the alignment mark structure includes:
the first alignment mark disposed in the first pad insulating layer at a same level as the first redistribution pad and including strip patterns spaced apart from each other;
a second alignment mark disposed on the lower surface of the first pad insulating layer; and
an alignment mark hole disposed in the second alignment mark.

9. The semiconductor package of claim 1, wherein the alignment mark structure includes:
the first alignment mark disposed in the first pad insulating layer and including strip patterns;
a second alignment mark disposed in the first pad insulating layer at a same level as the first redistribution pad; and
an alignment mark hole disposed in the first pad insulating layer.

10. The semiconductor package of claim 1, wherein
the package body is a wiring board having a through hole in an inner area, and
the semiconductor chip is embedded in the through hole and sealed by an encapsulation layer.

11. The semiconductor package of claim 1, wherein
the package body is a semiconductor substrate having a through hole in an inner area, and
the semiconductor substrate constituting the package body further includes a body wiring structure penetrating upper and lower surfaces thereof.

12. The semiconductor package of claim 1, wherein
the package body is an encapsulation layer sealing the semiconductor chip, and
the encapsulation layer constituting the package body further includes the body wiring structure penetrating upper and lower surfaces thereof.

13. A semiconductor package, comprising:
a package body having a fan-in area and a fan-out area at least partially surrounding the fan-in area, wherein a body wiring structure is formed in the fan-out area of the package body;
a semiconductor chip disposed in the fan-in area;
a first redistribution structure disposed on a lower surface of the package body and a lower surface of the semiconductor chip, and comprising a first redistribution element in each of the fan-in area and the fan-out area;
a first redistribution pad disposed on a lower surface of the first redistribution structure and electrically connected to the first redistribution element;
a ball land layer disposed on a lower surface of the first redistribution pad;
a first pad insulating layer disposed on the lower surface of the first redistribution structure and insulating the first redistribution pad and the ball land layer;
an alignment mark structure disposed in the fan-out area and spaced apart from the first redistribution pad, and disposed inside or on a lower surface of the first pad insulating layer; and
a first solder ball disposed on the lower surface of the first redistribution pad and a lower surface of the ball land layer.

14. The semiconductor package of claim 13, wherein the package body includes a wiring substrate having a through hole in an inner area, a semiconductor substrate having a through hole in an inner area, and/or an encapsulation layer sealing the semiconductor chip.

15. The semiconductor package of claim 13, wherein the alignment mark structure includes:
a first alignment mark disposed in the first pad insulating layer at a same level as the first redistribution pad; and
an alignment mark hole disposed in the first alignment mark at a same level as the ball land layer in the first pad insulating layer.

16. The semiconductor package of claim 15, wherein a second alignment mark is embedded in the alignment mark hole.

17. The semiconductor package of claim 13, wherein the alignment mark structure includes:
an alignment mark hole disposed in the first pad insulating layer at a same level as the ball land layer; and
an alignment mark embedded in the alignment mark hole.

18. The semiconductor package of claim 13, wherein the alignment mark structure includes:
the first alignment mark disposed in the first pad insulating layer and including strip patterns spaced apart from each other;
a second alignment mark disposed on the lower surface of the first pad insulating layer; and
an alignment mark hole disposed in the second alignment mark.

19. The semiconductor package of claim 13, wherein a capacitor electrically connected to the first redistribution element is formed in a lower portion of the first redistribution structure.

20. A semiconductor package, comprising:
a lower package; and
an upper package stacked on the lower package,
wherein the lower package comprises:
a package body having a fan-in area and a fan-out area at least partially surrounding the fan-in area, wherein a body wiring structure is formed in the fan-out area of the package body;
a lower semiconductor chip disposed in the fan-in area;
a first redistribution structure disposed on a lower surface of the package body and a lower surface of a lower semiconductor chip, and comprising a first redistribution element in each of the fan-in area and the fan-out area;
a first redistribution pad disposed on a lower surface of the first redistribution structure and electrically connected to the first redistribution element;
a ball land layer disposed on a lower surface of the first redistribution pad;
a first pad insulating layer disposed on the lower surface of the first redistribution structure and insulating the first redistribution pad and the ball land layer;
an alignment mark structure disposed in the fan-out area and spaced apart from the first redistribution pad, and disposed inside or on a lower surface of the first pad insulating layer;
a first solder ball disposed on a lower surface of each of the first redistribution pad and the ball land layer;
a second redistribution structure disposed on an upper surface of the package body and an upper surface of the lower semiconductor chip, and comprising a second redistribution element in each of the fan-in area and the fan-out area; and
a second redistribution pad electrically connected to the second redistribution element, wherein the upper package comprises:
a second solder ball disposed on the second redistribution pad; and
an upper semiconductor chip mounted on the second redistribution structure and electrically connected through the second solder ball.
